(19) United States
(12) Patent Application Publication
(10) Pub. No.: US 2006/0145707 A1
(43) Pub. Date: Jul. 6, 2006

(54) Device for generating electrical signal corresponding to change in position or posture

(76) Inventor: Yasuhiko Ooe, Fukuoka (JP)

Correspondence Address: SUGHRUE MION, PLLC, 2100 PENNSYLVANIA AVENUE, N.W., SUITE 800, WASHINGTON, DC, 20037, US

(21) Appl. No.: 10/562,139

(22) PCT Filed: Jun. 28, 2004
(86) PCT No.: PCT/JP04/09452

§ 371 Date: Dec. 23, 2005

(30) Foreign Application Priority Data
Jun. 30, 2003 (JP) 3003-187483

(51) Int. Cl. G01R 27/26

(52) U.S. Cl. 324/661

(57) ABSTRACT

[Problem] To provide a compact device for generating an electrical signal corresponding to a change in position or posture, which can be used in such as posture control of a ship, a motor vehicle, aircraft, or the like, and detection of action or posture of various parts of a human body.

[Means for Resolution] A device for generating an electrical signal corresponding to a change in posture includes: a container which is formed of an electrical insulating material and is fixed to an electrode holder formed of an electrical insulating material and in which a fluid dielectric is sealed with a volume ratio sufficient to have an angle of inclination with respect to a free surface of the fluid dielectric; a plurality of pairs of peripheral electrodes disposed at positions which are symmetrical about a central point of a cross section of the container at a predetermined interval with an inner peripheral surface of the container; and a pair of counter electrodes which are electrically insulated from each other and are respectively disposed at an upper surface of the electrode holder which serves as a bottom of the container and at a lower surface of a ceiling of the container at the central point of the cross section of the container, a voltage being applied to the pair of counter electrodes.

### TECHNICAL FIELD

The present invention relates to a device for generating electrical signal corresponding to a change in position or posture which can be used for detection of diastrophism, posture control of a ship, an aircraft, a motor vehicle, or the like, and detection of the action or posture of various parts of a human body. Further, it can be also used for the track-levels, which might be used in the fields of a manipulator, architecture, or civil engineering, the rocking control system for a mega-float or artificial floating structures, a steel tower, utility poles, a bridge beam, or the like.

### BACKGROUND ART

As means for detecting a change in the posture (inclination) of a ship, which is used for posture control of a ship, an electrical signal generator is disclosed in JP-A-11-118412, for example. A fluid dielectric of which volume is set to a predetermined ratio to the volume of a container is filled in the container, and at least a pair of electrodes having predetermined flat surfaces are immersed in this fluid dielectric in advance. Difference of the surface area being immersed in the fluid dielectric occurs between said pair of the electrodes in correspondence with the magnitude of the inclination of the container. This surface area difference causes so-called developing electrostatic capacity, whereby the voltage signal corresponding thereto can be obtained by connecting electrically said developing electrostatic capacity to the resistance

The above-described conventional art has been frequently applied to the limited usage of the posture measurement under specific experimental environment or of a static positional measuring type. In this sense, measurement becomes extremely difficult with respect to an object whose inclination direction changes over the time. In addition, the above-described conventional device has a problem in that its structure becomes complex, which increases the manufacturing cost. Therefore, an object of the invention is to provide a device for generating an electrical signal corresponding to a change in position or posture with a simple structure of which manufacturing cost is inexpensive, and enables measurement of a change in the displacement or posture of an object in every conceivable scene and place.

### DISCLOSURE OF INVENTION

To attain the above object, in accordance with a first aspect of the invention there is provided a device for generating an electrical signal corresponding to a change in posture comprising: a container which is formed of an electrical insulating material and is tightly fixed to an electrode holder formed of an electrical insulating material and in which a fluid dielectric is sealed with a volume ratio sufficient to have an angle of inclination with respect to a free surface of the fluid dielectric; a plurality of pairs of peripheral electrodes (4) disposed at positions in such a way that each of said plurality of pairs of peripheral electrodes are symmetrical arranged perpendicular to the electrode holder in respect of a central point of a cross section of the container so as to be apart from an inner peripheral surface of the container with a predetermined interval therefrom; and a pair of counter electrodes (3), being electrically insulated from each other, which are opposed each other along an imaginary line perpendicular from a central point of the cross section of the container, each of said pair of counter electrodes being perpendicular to an upper surface of the electrode holder, serving as a bottom of the container, or perpendicular to a lower surface of a ceiling part of the container, characterized in that an external voltage is applied to the pair of counter electrodes so that an electrical signal corresponding to a change in posture can be generated. According to this aspect of the invention, it is possible to detect with an extremely compact and simple structure the inclination in one of an X-axis direction or a Y-axis direction of the container, simultaneously detect the inclination in both directions thereof, and concurrently detect a change in the inclination (posture) in a Z-axis direction by combining the devices.

In accordance with a second aspect of the invention, there is provided the device for generating an electrical signal corresponding to a change in posture according to the first aspect, wherein each of the counter electrodes has a flat surface. According to this aspect of the invention, since the distance between the counter electrodes and the peripheral electrodes can be made close to each other, it is possible to overcome the drawback that accurate detection of the electrostatic capacity becomes impossible when the free surface of the fluid dielectric is located in between the counter electrode and the peripheral electrode.

In accordance with a third aspect of the invention, there is provided the device for generating an electrical signal corresponding to a change in posture according to the first or second aspect, wherein each of the peripheral electrodes extends from the ceiling and the bottom, respectively, of the container, and has a nonconductive portion or is split in an axial direction thereof.

In accordance with a fourth aspect of the invention, there is provided the device for generating an electrical signal corresponding to a change in posture according to the third aspect, wherein power supply electrodes integrally extend from the bottom to the ceiling of the container instead of the counter electrodes.

In accordance with a fifth aspect of the invention, there is provided a device for generating an electrical signal corresponding to a change in posture comprising: a spherical container which is formed of an electrical insulating material and in which a plurality of electrodes, to which a voltage is applied and each has an arcuate surface, are fixed to an inner peripheral surface thereof vertically symmetrically, a fluid dielectric being sealed therein with a volume ratio sufficient to have an angle of inclination with respect to a free surface of the fluid dielectric; and a pair of counter electrodes which are electrically insulated from each other and are respectively disposed at a lower end portion and an upper end portion which share a segment passing through a central point of the spherical container, a voltage being applied to the pair of counter electrodes. According to this aspect of the invention, it is possible to detect even a change in the angle of inclination in units of seconds, and the device in accordance with the invention is suitable in a case where detection of fine amounts of change in posture is required.

In accordance with a sixth aspect of the invention, there is provided a device for generating an electrical signal corresponding to a change in posture comprising: a polygonal container which is formed of an electrical insulating material and in which a plurality of electrodes each having a flat surface are fixed to an inner peripheral surface thereof vertically symmetrically, a fluid dielectric being sealed therein with a volume ratio sufficient to have an angle of inclination with respect to a free surface of the fluid dielectric; and a pair of counter electrodes which are electrically insulated from each other and are respectively disposed at mutually opposing portions of the container, a voltage being applied to the pair of counter electrodes.

In accordance with a seventh aspect of the invention, there is provided the device for generating an electrical signal corresponding to a change in posture according to any one of the first to sixth aspects, wherein a high frequency voltage is applied to an electrical-signal generating means for outputting a voltage corresponding to a difference in an developing electrostatic capacity ascribable to a difference in an area of contact with the fluid dielectric between at least one pair of electrodes to which the voltage is applied in the container in which the fluid dielectric with a volume less than a content volume of the container is accommodated, frequency modulation corresponding to the inclination of the container is provided for a carrier wave generated by a high frequency oscillator, and this signal is subjected to FM demodulation.

In accordance with an eighth aspect of the invention, there is provided a device for generating an electrical signal corresponding to a change in position comprising: a hollow conductor; a conductor coated with an electrical insulating material and fitted in the hollow conductor, the conductor being linearly displaceable; means for applying a voltage across the hollow conductor and the conductor coated with the electrical insulating material; and means for obtaining as an electrical signal a change in electrostatic capacity corresponding to an amount of insertion or pulling-out displacement between the hollow conductor and the conductor coated with the electrical insulating material. According to this aspect of the invention, the amount of linear displacement of the measuring object can be detected with high accuracy. Therefore, the device can be suitably used in cases where it is necessary to ascertain the manufacturing process of precision machinery, the distance between respective joints of a robot, and the amount of displacement of members in a motor vehicle, aircraft, and the like.

In accordance with a ninth aspect of the invention, there is provided a device for generating an electrical signal corresponding to a change in position comprising: a flexible hollow conductor; a flexible conductor coated with an electrical insulating material and fitted in the hollow conductor, the flexible conductor being linearly displaceable in an axial direction; means for applying a voltage across the flexible hollow conductor and the flexible conductor coated with the electrical insulating material; and means for obtaining as an electrical signal a change in electrostatic capacity corresponding to an amount of insertion or pulling-out displacement between the flexible hollow conductor and the flexible conductor coated with the electrical insulating material. According to this aspect of the invention, since it is possible to measure the amount of displacement of a curved locus, the device can be suitably used in the fields of civil engineering, architecture, and machinery.

In accordance with a ninth aspect of the invention, there is provided a device for generating an electrical signal corresponding to a change in position or posture wherein the pair of the devices for generating an electrical signal corresponding to a change in posture according to any one of the first to third aspects are respectively attached to both ends or spaced-apart midway portions of a device for generating an electrical signal corresponding to a change in position which comprises a hollow conductor, a conductor coated with an electrical insulating material and fitted in the hollow conductor, the conductor being linearly displaceable, means for applying a voltage across the hollow conductor and the conductor coated with the electrical insulating material, and means for obtaining as an electrical signal a change in electrostatic capacity corresponding to an amount of insertion or pulling-out displacement between the hollow conductor and the conductor coated with the electrical insulating material. According to this aspect of the invention, it is possible to detect concurrently the amount of linear displacement between members and changes in the angle of inclination (posture) in the X-, Y-, and Z-axis directions of a member.

In accordance with a 10th aspect of the invention, there is provided a device for generating an electrical signal corresponding to a change in position or posture wherein the pair of the devices for generating an electrical signal corresponding to a change in posture according to any one of the first to third aspects are respectively attached to both ends or spaced-apart midway portions of a device for generating an electrical signal corresponding to a change in position which comprises a flexible hollow conductor, a flexible conductor coated with an electrical insulating material and fitted in the hollow conductor, the flexible conductor being linearly displaceable in an axial direction, means for applying a voltage across the flexible hollow conductor and the flexible conductor coated with the electrical insulating material, and means for obtaining as an electrical signal a change in electrostatic capacity corresponding to an amount of insertion or pulling-out displacement between the flexible hollow conductor and the flexible conductor coated with the electrical insulating material. According to this aspect of the invention, it is possible to concurrently detect, for example, the amount of displacement of various parts of a human body and a change in the posture thereof.

In accordance with an 11th aspect of the invention, there is provided a device for generating an electrical signal corresponding to a change in position wherein at least one pair of members consisting of conductors are attached to a radially expandable and contractible annular or polygonal member in such a manner as to oppose each other in a radial direction, and a voltage is applied across the at least one pair of members consisting of the conductors, so as to generate an electrical signal based on a change in electrostatic capacity corresponding an amount of displacement inmutually moving away and approaching of the at least one pair of members consisting of the conductors due to the expansion or contraction of the radially expandable and contractible annular or polygonal member. According to this aspect of the invention, it is possible to quantitatively detect the expansion or contraction of muscles at various parts of a human body including the wrist, the thigh, the calf, and the like. In addition, since the condition of breathing can be detected by wearing the devices on the breast, it is possible to automatically ascertain the symptom of apnea and reliably take a preventive measure by such as issuing an alarm.

### BRIEF DESCRIPTION OF DRAWINGS

FIG. 1 is a vertical cross-sectional view of a device for generating an electrical signal corresponding to a change in posture in accordance with an embodiment of the invention;

FIG. 2 is a horizontal cross-sectional view of the device for generating an electrical signal corresponding to a change in posture shown in FIG. 1;

FIG. 3 is a vertical cross-sectional view of the device for generating an electrical signal corresponding to a change in posture in accordance with another embodiment of the invention;

FIG. 4 is a vertical cross-sectional view of the device for generating an electrical signal corresponding to a change in posture in accordance with still another embodiment of the invention;

FIG. 5 is a vertical cross-sectional view of the device for generating an electrical signal corresponding to a change in posture in accordance with a further embodiment of the invention;

FIG. 6 is a vertical cross-sectional view illustrating a form in which the device for generating an electrical signal corresponding to a change in posture in accordance with a still further embodiment of the invention is mounted on a substrate;

FIG. 7 is a vertical cross-sectional view illustrating a form in which the device for generating an electrical signal corresponding to a change in posture shown in FIG. 5 is mounted on the substrate;

FIG. 8 is a schematic diagram illustrating another example of peripheral electrodes;

FIG. 9 is a perspective view illustrating the positional relationship between a container on the one hand, and counter electrodes and peripheral electrodes on the other hand, as well as coordinate axes in tilting directions of the container, in the devices for generating an electrical signal corresponding to a change in posture in accordance with the invention shown in FIGS. 1 to 8;

FIG. 10 is a schematic diagram of the device for generating an electrical signal corresponding to a change in posture in accordance with a further embodiment of the invention;

FIG. 11 is a vertical cross-sectional view illustrating a form in which the device for generating an electrical signal corresponding to a change in posture shown in FIG. 10 is mounted on the substrate;

FIG. 12 is a circuit diagram illustrating an integrating circuit used for obtaining an electrical signal by the device for generating an electrical signal corresponding to a change in posture in accordance with the invention;

FIG. 13 is a circuit diagram illustrating in a simplified form the circuit shown in FIG. 12;

FIG. 14 is a circuit diagram illustrating a differential integrating circuit used for obtaining an electrical signal by the device for generating an electrical signal corresponding to a change in posture in accordance with the invention;

FIG. 15 is a circuit diagram illustrating in a simplified form the circuit shown in FIG. 14;

FIG. 16 is a perspective view illustrating a detecting element of a device for generating an electrical signal corresponding to a change in position in accordance with the invention;

FIG. 17 is a perspective view illustrating a flexible detecting element of the device for generating an electrical signal corresponding to a change in position in accordance with the invention;

FIG. 18 is a front elevational view illustrating a state in which the devices for generating an electrical signal corresponding to a change in posture in accordance with the invention are applied to various parts of the human body;

FIG. 19 is a schematic diagram illustrating a state in which the devices for generating an electrical signal corresponding to a change in posture in accordance with the invention are attached to both ends of the detecting element of the device for generating an electrical signal corresponding to a change in position shown in FIG. 16;

FIG. 20 is a front elevational view illustrating a state in which an assembly, in which the devices for generating an electrical signal corresponding to a change in posture in accordance with the invention are attached to both ends of the detecting element of the device for generating an electrical signal corresponding to a change in position shown in FIG. 17, is applied to the body;

FIG. 21 is a perspective view illustrating a further embodiment of the device for generating an electrical signal corresponding to a change in position in accordance with the invention, which detects a change in the electrostatic capacity corresponding to a change in the distance between mutually opposing electrodes;

FIG. 22 is a block diagram illustrating an example of a configuration Web server and a computer in which three-dimensional posture information corresponding to the position or posture of an object measured by the device of the invention is used as a constituent element; and

FIG. 23 is a block diagram illustrating an embodiment in which the action of a human body is recorded by using a Web PC shown in FIG. 22.

### BEST MODE FOR CARRYING OUT THE INVENTION

Hereafter, a description will be given to preferred embodiments of the invention with reference to the drawings.

The device for generating an electrical signal corresponding to a change in position or posture makes use of the phenomenon such that an electrostatic capacity changes between electrodes in correspondence with the displacement of a measuring object or a change in its posture, by which this change can be obtained in the form of an electrical signal such as a voltage. Further, by applying a high frequency voltage or a DC voltage to the electrodes, where in the former case a change in the electrostatic capacity in a resonant circuit of an oscillator is mainly detected as a change in the voltage, while in the latter case, a change in the electrostatic capacity based on the difference in the contact areas between each electrode and the fluid dielectric, which occurs due to the inclination of the measuring object, is detected as a change in the voltage. Accordingly, in the case where the high frequency voltage is applied across the electrodes, frequency modulation can be performed to a carrier wave, which is generated by the oscillator, in correspondence with the angle of inclination of the measuring object. If the signal obtained in this way is subjected to FM demodulation, it is possible to obtain a signal representing the angle of inclination. In the case where the signal is obtained by providing FM demodulation, it can be said that the sensor device that is residual to the electrical noises can be provided.

On the other hand, in the case where a DC voltage is applied across the electrodes, the change in the angle of inclination can be obtained as an electrical signal by a differential amplifier.

### Embodiments

### First Embodiment

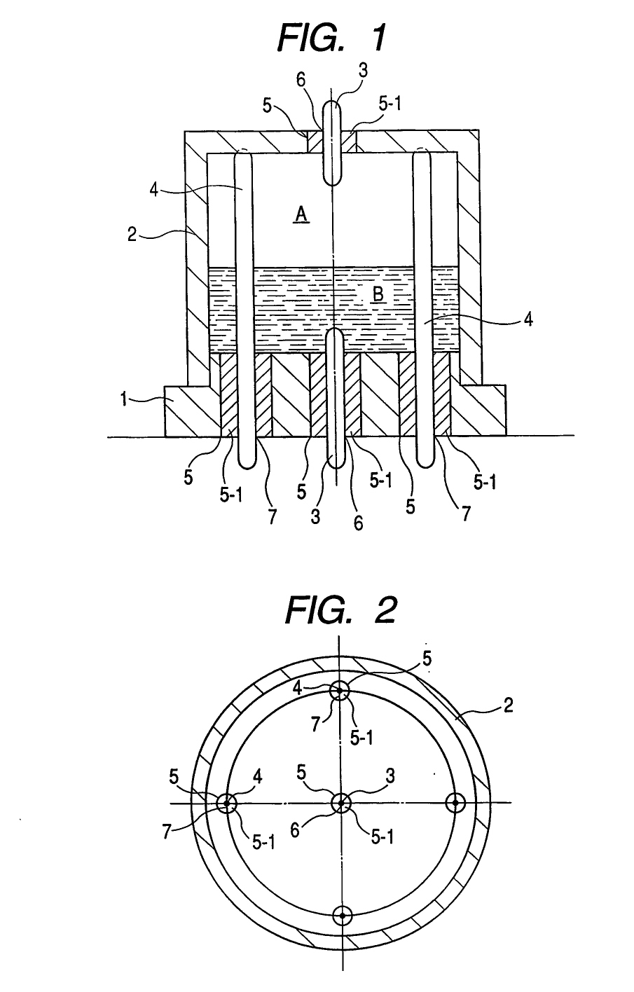

FIG. 1 shows a vertical cross section of the device for generating an electrical signal corresponding to a change in posture in accordance with an embodiment of the invention. In FIG. 1, reference numeral 1 denotes an electrode holder, which is formed of an electrical insulating material such as a resin, acrylic, glass, or the like. The electrode holder 1 has a flat portion formed on its upper surface, and bored in the electrode holder 1 are holes 5 for fitting a bush 5-1 for tightly fitting a counter electrode 3 therein and for fitting bushes 5-1 for tightly fitting peripheral electrodes 4 therein. The bushes 5-1 are tightly fitted in these bush fitting holes 5, as shown in FIGS. 1 and 2. The bushes 5-1 are formed of an electrical insulating material which is flexible, such as silicone rubber.

The counter electrodes 3 and the peripheral electrodes 4 are formed of an electrically conductive material which is chemically stable (whose ionization tendency is low), e.g., 18K gold (Au). The counter electrodes 3 and the peripheral electrodes 4 are 0.6 mm φ rods. As shown in FIG. 1, the pair of counter electrodes 3 are tightly fitted in counter-electrode fitting holes 6 bored in the bushes 5-1 with being opposed each other along an imaginary line perpendicular from a central point in a cross section of a container 2 so that one of the counter electrodes is extending perpendicular from a ceiling side portion of the container and the other one of the counter electrodes is extending perpendicular from the upper surface of the electrode holder 1. Respective one ends of the counter electrodes 3 project a predetermined length in such a manner as to face the inner space of the container 2. Further, a high frequency voltage or a DC voltage is applied across the respective counter electrodes 3 and the peripheral electrodes 4. As shown in FIGS. 1 and 2, the peripheral electrodes 4 are disposed at circumferentially equal intervals with a predetermined interval from an inner wall surface of the container 2, i.e., with an interval of 0.3 mm in this embodiment. One end of each peripheral electrode 4, or an upper end thereof as viewed in FIG. 1, is fitted in the ceiling of the container 2, and upper end lower ends thereof are respectively fixed in the container 2 and the electrode holder 1. The counter electrodes 3 and the peripheral electrodes 4 in this embodiment have a diameter of 0.6 mm, their surfaces are ground and flat, and surface areas of the four peripheral electrodes 4 are made uniform.

As shown in FIG. 2, the pair of counter electrodes 3 are respectively fitted tightly in counter-electrode fitting holes 6 bored in the centers of the flat surfaces of the bushes 5-1 which are fitted in the brush fitting holes 5 bored in the centers of flat surfaces of both the ceiling of the container 2 and an upper stage portion of the electrode holder 1 which is fitted to an inner peripheral surface of the container 2. In the state shown in FIG. 1, the lower counter electrode 3 is immersed in a fluid dielectric B, and when the top and the bottom of the container 2 are inverted, the counter electrode 3 disposed in the ceiling portion of the container 2 is immersed in the fluid dielectric B. Accordingly, either one of the upper counter electrode 3 and the lower counter electrode 3 is designed to have an electrostatic capacity with respect to the peripheral electrodes 4 through the fluid dielectric B. The electrostatic capacity changes in correspondence with a change in the angle of inclination in either an X-axis direction or a Y-axis direction or a composite direction of the container 2, and this electrostatic capacity can be detected as an electrical signal.

Also, in a case where an embodiment is adopted in which the counter electrodes 3 are wholly embedded in the ceiling of the container 2 and in the bottom thereof served by the upper surface of the electrode holder 1, the device can be functioning as the device for generating an electrical signal corresponding to a change in posture in accordance with the invention.

As shown in FIGS. 1 and 2, the peripheral electrodes 4 are disposed in the ceiling portion of the container 2 and the electrode holder 1 at positions of the intersections which are formed on an imaginary concentric circle of the container 2 so as to have a predetermined interval from the inner wall surface thereof, where said intersections are determined in such a way that an imaginary line segment passing through the central point of the flat surface of the upper stage portion of the electrode holder 1 fitting to the inner peripheral surface of the container 2, and another imaginary line segment perpendicular to the aforementioned line segment with passing through the same central point are intersected on said imaginary concentric circle. Thus, the peripheral electrodes 4 are formed as a pair of peripheral electrodes 4 in the X-axis direction and a pair of peripheral electrodes 4 in the Y-axis direction.

In the invention, as for the peripheral electrodes 4, it is possible to adopt an embodiment in which they respectively extend from the bottom and the ceiling of the container 2 and have nonconductive portions or are split in their axial directions, as shown in FIG. 8. In that case, instead of the counter electrodes 3, it is also possible to use power supply electrodes which integrally extend from the ceiling to the bottom of the container 2.

As the counter electrodes 3 and the peripheral electrodes 4, a material having a low ionization tendency, e.g., 18K gold (Au), is suitable. Meanwhile, a material exhibiting low impedance between electrodes is preferable. If the impedance between electrodes is high, various kinds of noise is picked up and cause a measurement error. If the impedance is conversely excessively low, it results not only in an increase in power consumption but in the loss of function due the plating of the electrodes. Therefore, the material of the counter electrodes 3 and the peripheral electrodes 4 is determined by taking these factors into consideration.

The container 2 has a hollow cylindrical shape, and its ceiling portion is closed. As for its lower end opening, its inner peripheral surface is tightly fitted to an outer peripheral surface of the upper stage portion of the electrode holder 1, as shown in FIG. 1. The container 2 is formed of an electrical insulating material, and is formed of an acrylic-, polyester-, or polyamide-based synthetic resin or the like in this embodiment. As shown in FIG. 1, the fluid dielectric B is filled in the inner space of the container 2 with a volume ratio sufficient to form an inclined surface between its free surface and an inner surface of the container 2. In this embodiment, the fluid dielectric B having a volume of 50% of the internal volume of the container 2 is filled. Reference character A denotes a gas portion, or air in this embodiment. Fluids which are not miscible, such as water and oil, may be filled in the portions A and B of the container 2.

In the invention, as the fluid dielectric B, it is possible to use solutions including, as a solvent, ethylene glycol, ethylene glycol monomethyl ether, γ-butyrolactone, N-methylformamide, or the like, and, as a solute, adipic acid, maleic acid, benzoic acid, phthalic acid, alicylic acid, or, as a basic solute, ammonia, aqueous ammonia, triethylamine, tetramethylammonium hydroxide, or the like.

### Second Embodiment

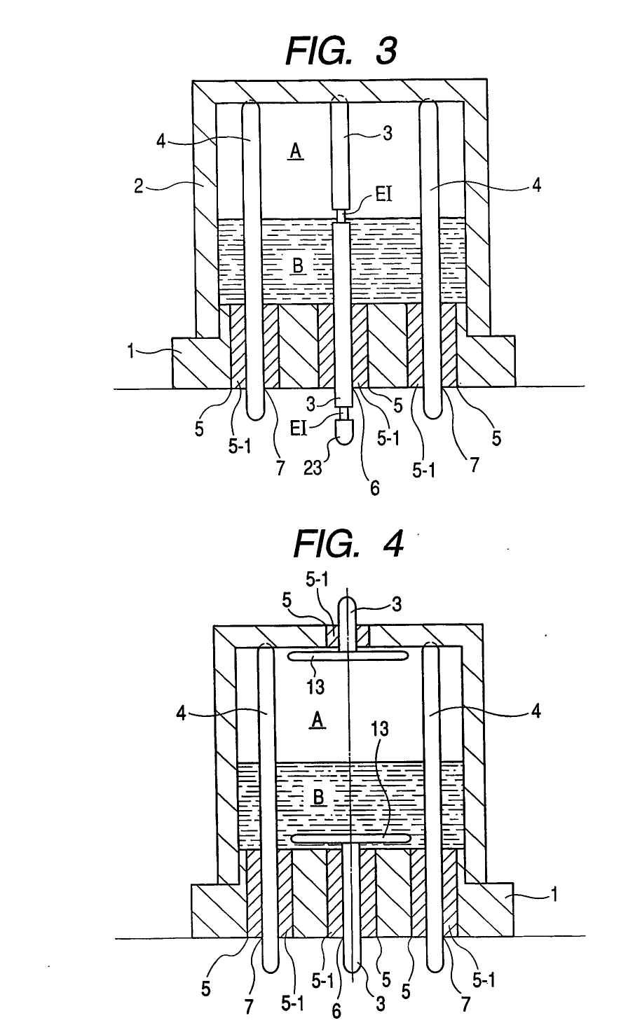

FIG. 3 shows another embodiment of the device for generating an electrical signal corresponding to a change in posture in accordance with the invention. Since the same reference numerals as those shown in FIGS. 1 and 2 denote the same constituent elements as those of the first embodiment, a description thereof will be omitted. In this embodiment, the counter electrodes 3 are electrically disposed as respectively independent electrodes, but are mechanically formed as an identical electrode, which is tightly fitted in the counter-electrode fitting hole 6 of the bush 5-1 in the electrode holder 1, an upper end portion thereof being fitted in a recessed portion at the ceiling of the container 2. The lower counter electrode 3 is made hollow, and an electrical insulator EI, through which an electrical conductor is passed, is fitted in this hollow portion. Further, the electrical conductor inside the electrical insulator EI is electrically coupled with the upper counter electrode 3, and is also electrically coupled with a lower counter-electrode connecting terminal 23. Meanwhile, a projecting portion of the lower counter electrode 3 projecting from a lower end face of the electrode holder 1 functions as the counter-electrode connecting terminal 23.

### Third Embodiment

FIG. 4 shows still another embodiment of the device for generating an electrical signal corresponding to a change in posture in accordance with the invention. Since the same reference numerals as those shown in FIGS. 1 and 2 denote the same constituent elements as those of the first embodiment, a description thereof will be omitted. As for the counter electrodes 3 in this embodiment, a form is adopted in which a pair of surface electrodes 13 are respectively formed at their end portions facing the interior of the container 2. Each surface electrode 13 has a circular flat surface portion, and its outside diameter should preferably be as practically large as possible within a range that does not come into contact with the peripheral electrodes 4. This arrangement makes it possible to overcome the problem that at the time the change in the electrostatic capacity due to the change in the angle of inclination of the container 2 is measured as a parameter, accurate measurement of the electrostatic capacity becomes impossible when the free surface of the fluid dielectric B is located in between the counter electrode 3 and the peripheral electrode 4. It goes without saying that in a case where the distance between the pair of peripheral electrodes 4 in the X-axis direction or the Y-axis direction is close, the device shown in FIG. 1 is capable of detecting a change in the angle of inclination (posture) of the container 2 with sufficiently high accuracy.

### Fourth Embodiment

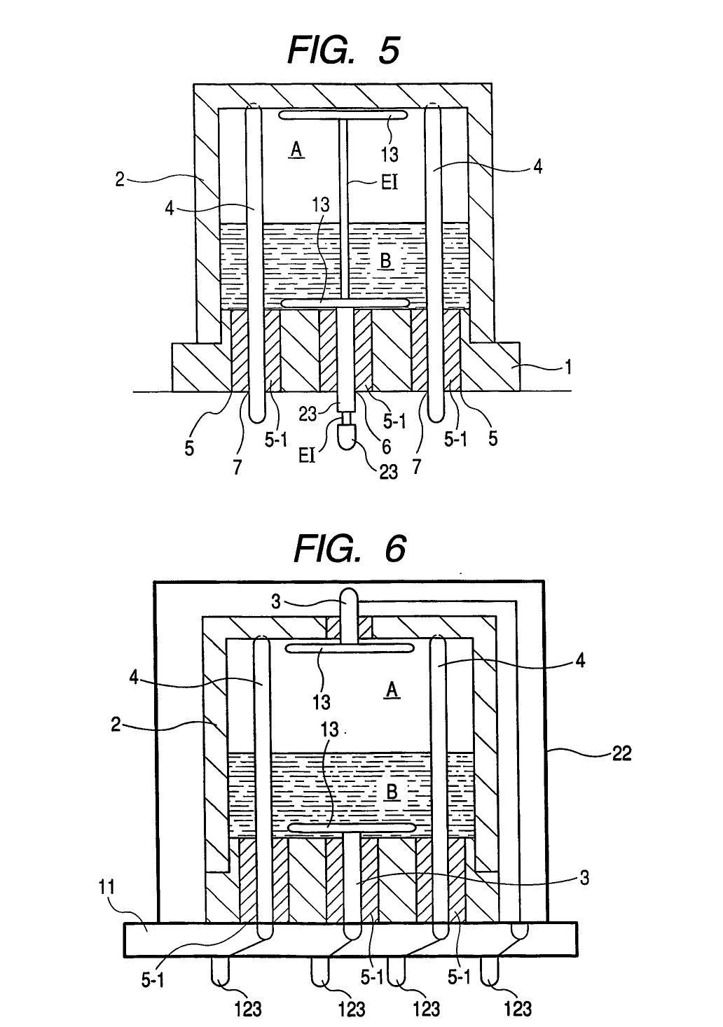

FIG. 5 shows a further embodiment of the device for generating an electrical signal corresponding to a change in posture in accordance with the invention. Since the same reference numerals as those shown in FIGS. 1 and 2 denote the same constituent elements as those of the first embodiment, a description thereof will be omitted. As for the counter electrodes 3 in this embodiment, the surface electrodes 13 are respectively formed at their end portions facing the interior of the container 2 in the same way as in the third embodiment. The upper surface electrode 13 and the lower surface electrode 13 are electrically disposed as mutually independent electrodes, but are mechanically formed as one and the same member by means of the electrical insulator EI having an electrical conductor inserted therein, the electrical insulator EI being connected to the lower planer electrode 13. The counter-electrode connecting terminal 23 is fitted in the counter-electrode fitting hole 6 of the bush 5-1 in the electrode holder 1. The electrical insulator EI is fitted in its hollow portion, and the surface electrode 13 abutting against the ceiling of the container 2 is fixed to an upper end of this electrical insulator EI. The electrical conductor is inserted in the electrical insulator EI. A voltage is applied to the upper surface electrode 13 through this electrical conductor independently of the lower surface electrode 13. The counter-electrode connecting terminal 23 is fixed to a lower end portion of the electrical insulator EI, and is connected to the electrical conductor inside the electrical insulator EI. In this embodiment, the mechanically integrated pair of surface electrodes 13 are fixed to the electrode holder 1 as the hollow counter-electrode connecting terminal 23 below the lower surface electrode 13 is inserted and fixed in the counter-electrode fitting hole 6. After making positional adjustment, the container 2 is fitted over and fixed to the upper stage portion of the electrode holder 1. Subsequently, the fluid dielectric B is sealed in by about 50% of the volume of the inner space of the container 2.

### Fifth Embodiment

FIG. 6 shows a still further embodiment of the device for generating an electrical signal corresponding to a change in posture in accordance with the invention. Since the same reference numerals as those shown in FIGS. 1 and 2 denote the same constituent elements as those of the first embodiment, a description thereof will be omitted. In this embodiment, the device for generating an electrical signal corresponding to a change in posture is structured to be accommodated in a housing 22 so as to be mounted on a substrate. As shown in FIG. 6, the device is accommodated in the housing 22 so as to protect the container 2, and is fixed to a substrate mounting base 11 having substrate connecting terminals 123 attached to a lower end face thereof, so as to facilitate the mounting on the substrate. The substrate connecting terminals 123 are electrically connected to a total of six terminals including the upper surface electrode 13, the lower surface electrode 13, and the peripheral electrodes 4 (four in this embodiment).

### Sixth Embodiment

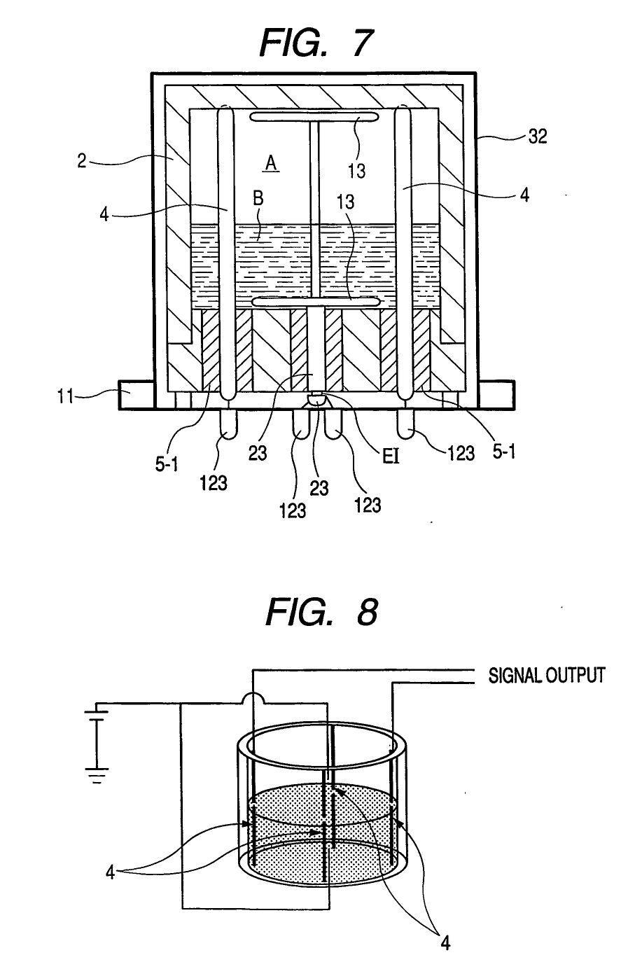

FIG. 7 shows a further embodiment of the device for generating an electrical signal corresponding to a change in posture in accordance with the invention. Since the same reference numerals as those shown in FIGS. 1 and 2 denote the same constituent elements as those of the first embodiment, a description thereof will be omitted. In this embodiment, the structure adopted is such that the device for generating an electrical signal corresponding to a change in posture shown in FIG. 5 is accommodated in a housing 32 so as to be mounted on a substrate. As shown in FIG. 7, the device is accommodated in the housing 32 so as to protect the container 2, and is fixed to a substrate mounting base 11 having substrate connecting terminals 123 attached to a lower end face thereof, so as to facilitate the mounting on the substrate. The substrate connecting terminals 123 are electrically connected to a total of six terminals including the upper surface electrode 13, the lower surface electrode 13, and the peripheral electrodes 4 (four in this embodiment).

In the embodiments of the invention shown in FIGS. 1 to 8, the peripheral electrodes 4 are formed in a rod-shape with a diameter of 0.6 mm, but substantially the same function can be achieved even in a case of adopting slender hair-like electrodes. In such a case, the peripheral electrodes 4 are arranged such that their upper and lower ends are fixed to the bottom and the ceiling of the container 2, and small tension is imparted thereto so as to maintain parallelism with the axis of the container 2. By providing such an arrangement, the device for generating an electrical signal corresponding to a change in posture can be made extremely compact.

In addition, although in the embodiments shown in FIGS. 4 to 8, the surface electrodes 13 are those having circular flat surfaces, it is also possible to use as the surface electrodes 13 those having triangular or other polygonal flat surfaces or those having elliptical flat surfaces.

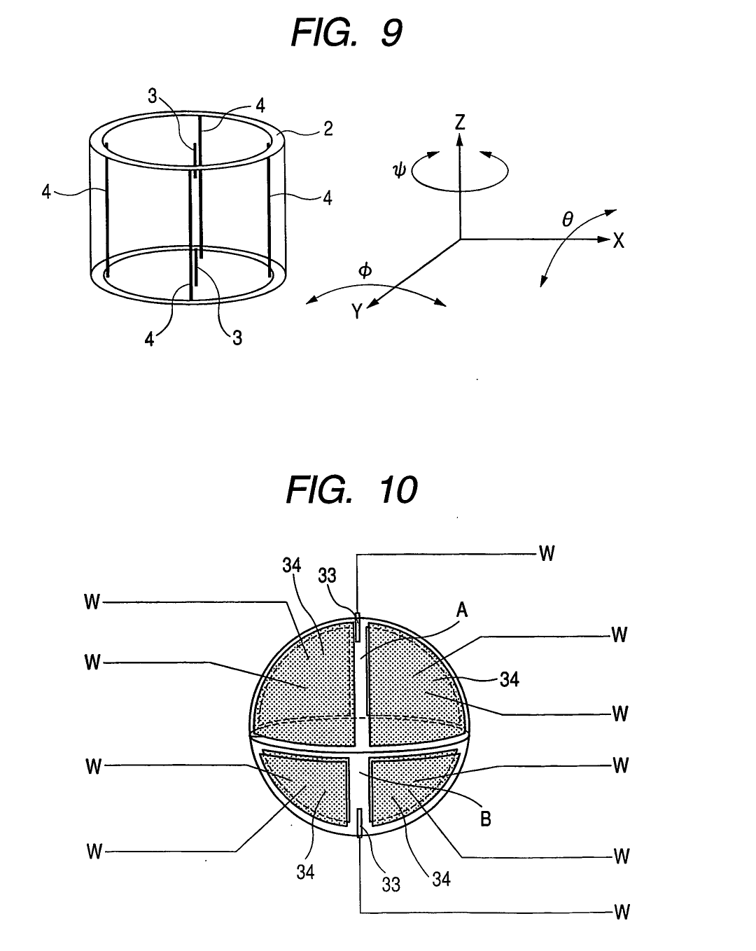

FIG. 9 shows the positional relationship between the container 2 on the one hand, and the counter electrodes 3 and the peripheral electrodes 4 on the other hand, as well as the relationship of coordinate axes, when the inclinations of three axes including the X-axis, the Y-axis, and the Z-axis are measured by using the devices for generating an electrical signal corresponding to a change in posture in accordance with the invention shown in FIGS. 1 to 8. An electrostatic capacity appears in a case where the fluid dielectric B having a volume of 50% of the content volume of the inner space of the container 2 is sealed in, and a voltage is applied across the lower counter electrode 3 and the peripheral electrodes 4. When the top and the bottom of the container 2 are inverted, the electrostatic capacity appears between the upper counter electrode 3 and the peripheral electrodes 4. If the container 2 rotates about the axes of the upper and lower counter electrodes 3 to cause the acceleration to act, and values of an electrostatic capacity C are uniform between the two pairs (or four) electrodes, the axis passing through the upper and lower counter electrodes 3 in the container 2 is vertical. If the container 2 tilts, the electrostatic capacity C changes between the two pairs (or four) electrodes, so that the angle of inclination in either one or a combination of the X-axis and the Y-axis can be measured from the amount of that change.

### Seventh Embodiment

FIG. 10 shows a further embodiment of the device for generating an electrical signal corresponding to a change in posture in accordance with the invention. In FIG. 10, reference numeral 33 denotes a counter projecting electrode. As shown in FIG. 10, the counter projecting electrodes 33 are respectively disposed at an upper portion and a lower portion of a spherical container 52, and respective one ends thereof project by a predetermined length in such a manner as to face the inner space of the spherical container 52. The counter projecting electrodes 33 may be planar. The spherical container 52 is a hollow sphere formed of a nonconductive material such as a resin. As shown in FIG. 10, planar electrodes 34 formed of a conductive material consisting of such as gold (Au) foils are respectively attached to the inner peripheral surface of the spherical container 52 in sections of respective upper and lower semispherical inner surfaces divided at a great circle of the sphere into at least four parts. Eight planar electrodes 34 are disposed for the entire inner peripheral surface of the spherical container 52. In a case where the inclination of any one of the X-axis, Y-axis, and Z-axis is detected, it is sufficient to dispose four (two pairs of) electrodes at the entire inner peripheral surface of the spherical container 52. As shown in FIG. 10, the arrangement provided is such that wirings w are connected to the respective planar electrodes to allow a voltage to be applied to the electrodes. As in this embodiment, if eight electrodes are disposed for the entire inner peripheral surface of the spherical container 52, it is possible to detect the inclinations of the spherical container 52 in the X-axis, Y-axis, and Z-axis at one time.

In this embodiment, the fluid dielectric B having a volume of 50% of the content volume is sealed inside the spherical container 52 (up to the position of the great circle of the sphere). When the top and the bottom of the spherical container 52 are inverted, the counter electrode 33 disposed at the upper portion of the spherical container 52 is immersed in the fluid dielectric B. Accordingly, either one of the upper counter electrode 33 and the lower counter electrode 33 comes to have an electrostatic capacity with respect to the planar electrodes 34 in the hemispheres of the spherical container 52 through the fluid dielectric B. The electrostatic capacity changes in correspondence with a change in the angle of inclination of the spherical container 52.

### Eighth Embodiment

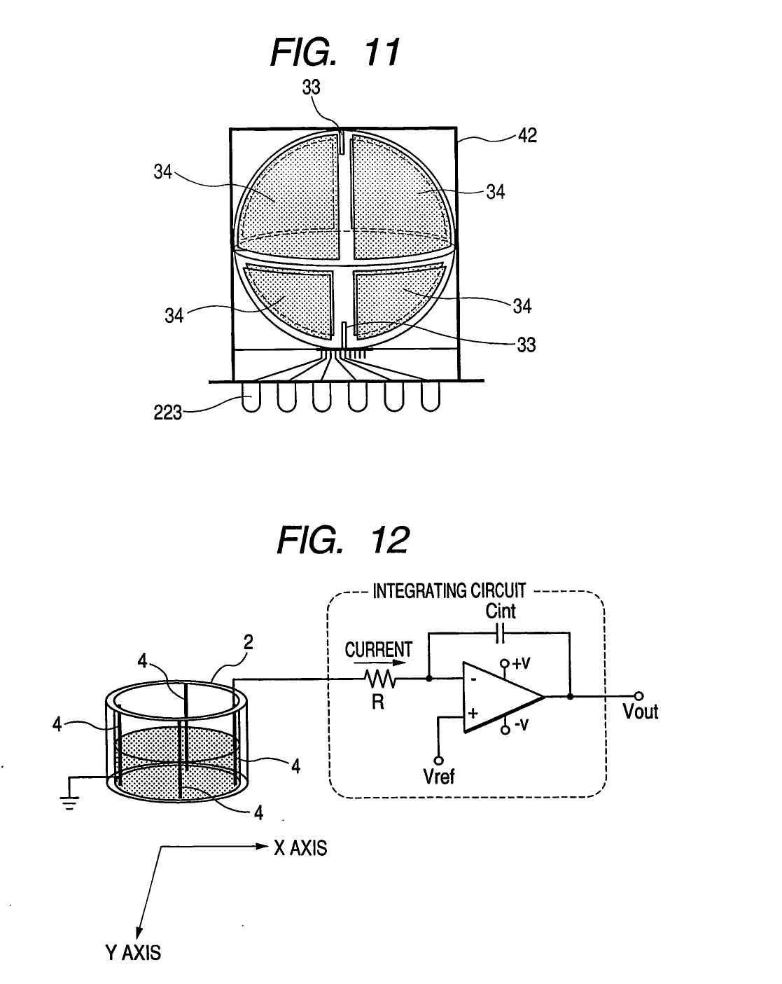

FIG. 11 shows a further embodiment of the device for generating an electrical signal corresponding to a change in posture in accordance with the invention. Since the same reference numerals as those shown in FIG. 9 denote the same constituent elements as those of the seventh embodiment, a description thereof will be omitted. In this embodiment, the structure adopted is such that the device for generating an electrical signal corresponding to a change in posture shown in FIG. 9 is accommodated in a housing 42 so as to be mounted on a substrate. As shown in FIG. 11, the device is accommodated in the housing 42 so as to protect the spherical container 52, and the housing 42 accommodating and fixing the device is fixed to the substrate mounting base 11 having substrate connecting terminals 223 attached to a lower end face thereof, so as to facilitate the mounting on the substrate. The substrate connecting terminals 223 are electrically connected to a total of 10 terminals including one upper counter electrode 33, one lower counter electrode 33, and 8 electrodes on the inner peripheral surface of the spherical container 52.

In the invention, it goes without saying that a polygonal container may be used instead of the spherical container 52 shown in FIGS. 10 and 11. In that case, the electrodes disposed on the inner wall surface of the container are not arcuate but flat surface electrodes.

Next, a description will be given to the operation of the device for generating an electrical signal corresponding to a change in posture in accordance with the invention. In the devices shown in FIGS. 1 to 11, if the container 2 or the spherical container 52 tilts, the area of contact with respect to the fluid dielectric B varies between the peripheral electrodes 4 or between the pair of planar electrodes 34. The electrostatic capacity that appears changes in correspondence with a change in this area of contact. The electrostatic capacity C is given by
C=ξₒ·ξ·S/t=8.855×10⁻¹²×ξ·S/t (1)

where C: electrostatic capacity
S: electrode area
t: electrode interval
ξₒ dielectric constant of vacuum (8.855×10⁻¹²)
ξ: specific dielectric constant of dielectric

Accordingly, the electrostatic capacity can be detected by the electrode area S and the electrode interval t. Since the electrode interval t is fixed in the embodiments of the invention described heretofore, the difference in the electrode area S, i.e., the area of contact with the fluid dielectric B, between the pair of peripheral electrodes 4 or the pair of planar electrodes 34, which occurs due to the tilting of the container 2 or the spherical container 52, as well as its change, are detected as the change in the electrostatic capacity C.

When an electrical signal is obtained by the device for generating an electrical signal corresponding to a change in posture in accordance with the invention shown in FIGS. 1 to 11, an integrating circuit such as the one shown in FIG. 12, for example, is used. As an electric current flowing across a capacitor is integrated each time the electrostatic capacity in the device changes, it is possible to obtain a voltage signal corresponding to the tilting of the device. A voltage Vₒᵤₜ outputted as the voltage signal is given by
Vₒᵤₜ=CV_{ref}
where V_{ref}: threshold voltage

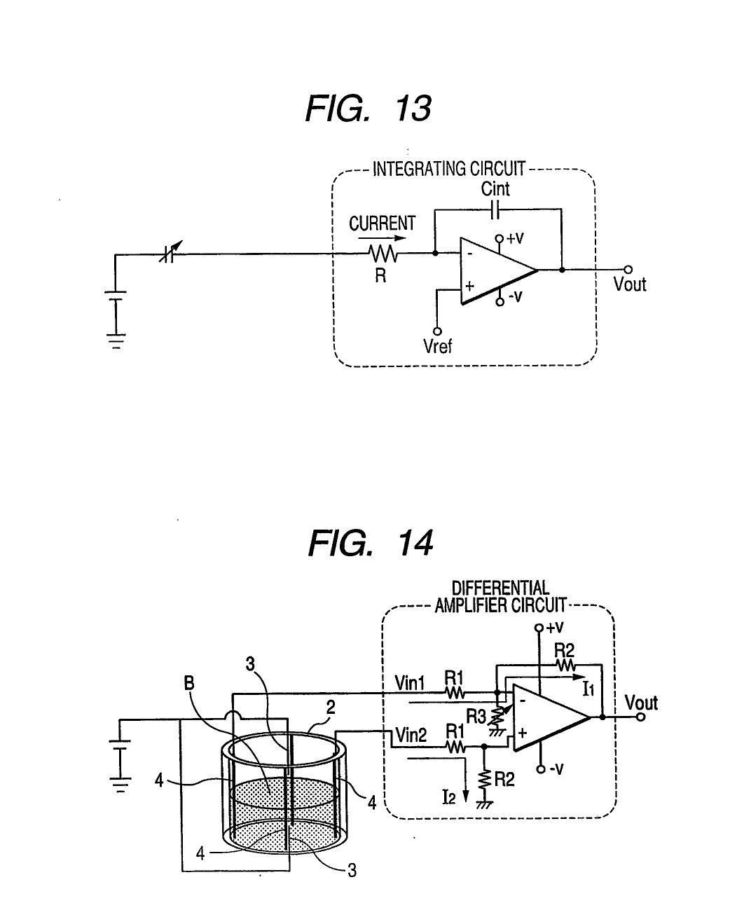

The inclination in one axis (e.g., X-axis) direction can be measured by the circuit shown in FIG. 12. To effect two-axis measurement in the X-axis direction and the Y-axis direction, two integrating circuits are required. To illustrate the integrating circuit shown in FIG. 12 in a more simplified form, the circuit diagram shown in FIG. 13 is obtained.

Although the integrating circuit shown in FIG. 12 is a kind of differential amplifier circuit, the degree of amplification is excessively large, so that it is impossible to expect stable operation. Accordingly, a differential amplifier circuit shown in FIG. 14 is used. The circuit shown in FIG. 14 functions such that the potential at an n point and the potential at a p point in the circuit become equal, so that the following formula holds:
V₁−R₁I₁=R₂I₂ (2)

Since the current does not flow into an operational amplifier whose input impedance is high, currents I₁ and I₂ are respectively given by
I₁=(V₁−Vₒ)/(R₁+R₂) (3)
I₂=V₂/(R₁+R₂) (4)

If the formulae are simplified by substitution, the output voltage Vₒ is given by the following formula:
Vₒ=(R₁/R₂)·(V₂−V₁) (5)

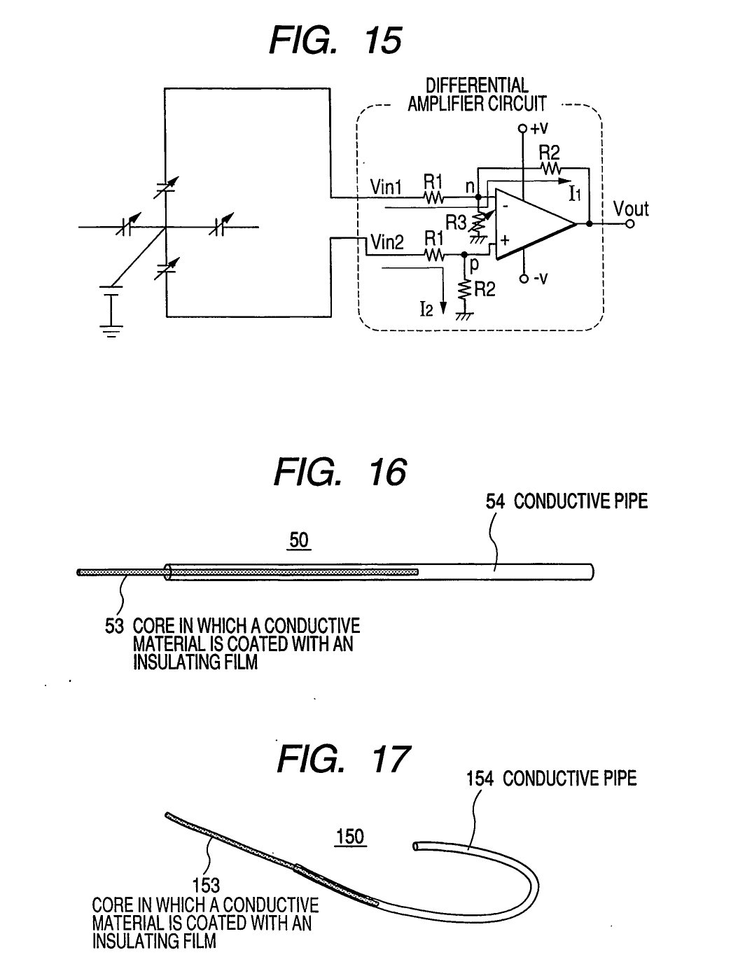

Consequently, it is possible to amplify only the potential difference at the input terminal. If the differential amplifier circuit shown in FIG. 14 is further simplified, a circuit diagram shown in FIG. 15 is obtained.

### Ninth Embodiment

FIG. 16 shows a detecting element of a device for generating an electrical signal corresponding to a change in position in accordance with the invention. In FIG. 16, reference numeral 50 denotes a detecting element for generating an electrical signal corresponding to a change in position; 53 denotes an insulator-coated conductor (core); 54 denotes a hollow conductor in which the insulator-coated conductor (core) 53 is fitted in such a way as to be capable of being inserted and pulled out. The insulator-coated conductor (core) 53 and the hollow conductor 54 are respectively provided with electrodes, and a voltage is applied across the insulator-coated conductor (core) 53 and the hollow conductor 54. An electrostatic capacity between the insulator-coated conductor (core) 53 and the hollow conductor 54 changes in correspondence with their amount of insertion or pulling-out displacement.

Since the insulator-coated conductor (core) 53 and the hollow conductor 54 are not in electrical contact with each other, noise is extremely small at the timing of the insertion and pulling-out displacement between them being measured by using the change in electrostatic capacity as a parameter. If the device for generating an electrical signal corresponding to a change in position in accordance with this embodiment of the invention is used, it is possible to measure the distance between two points on a noncontact basis. Therefore, the device can be used in various kinds of the industrial fields such as in the manufacturing process of precision machinery, the distance between respective joints of a robot, the operating state of parts in a motor vehicle or the like, the operating state of a flapper and other members in aircraft, and so forth.

### 10th Embodiment

FIG. 17 shows a detecting element of the device for generating an electrical signal corresponding to a change in position in accordance with the invention. In FIG. 17, reference numeral 150 denotes a flexible detecting element for generating an electrical signal corresponding to a change in position; 153 denotes a flexible insulator-coated conductor (core); 154 denotes a flexible hollow conductor in which the flexible insulator-coated conductor (core) 153 is fitted in such a way as to be capable of being inserted and pulled out. The flexible insulator-coated conductor (core) 153 and the flexible hollow conductor 154 are respectively provided with electrodes, and a voltage is applied across the flexible insulator-coated conductor (core) 153 and the flexible hollow conductor 154. An electrostatic capacity between the flexible insulator-coated conductor (core) 153 and the flexible hollow conductor 154 changes in correspondence with their amount of insertion or pulling-out displacement.

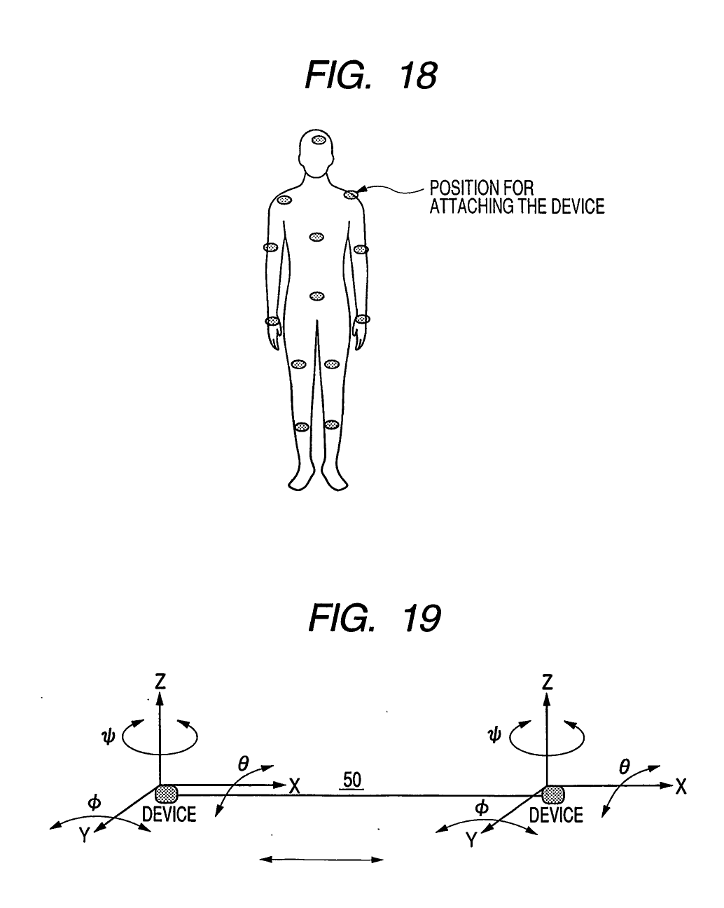

FIG. 18 shows a state in which the devices for generating an electrical signal corresponding to a change in posture in accordance with the invention shown in FIGS. 1 to 11 are applied to various parts of the body. It is thereby possible to as certain changes in inclination in the X-, Y-, and Z-axis directions of the various parts of the body.

FIG. 19 shows a state in which the devices for generating an electrical signal corresponding to a change in posture in accordance with the invention shown in FIGS. 1 to 11 are attached to both ends of the device for generating an electrical signal corresponding to a change in position shown in FIG. 16. It is thereby possible to ascertain the amounts of linear displacement of various parts of a machine tool or a robot and how much the various parts have tilted in the X-, Y-, and Z-axis directions.

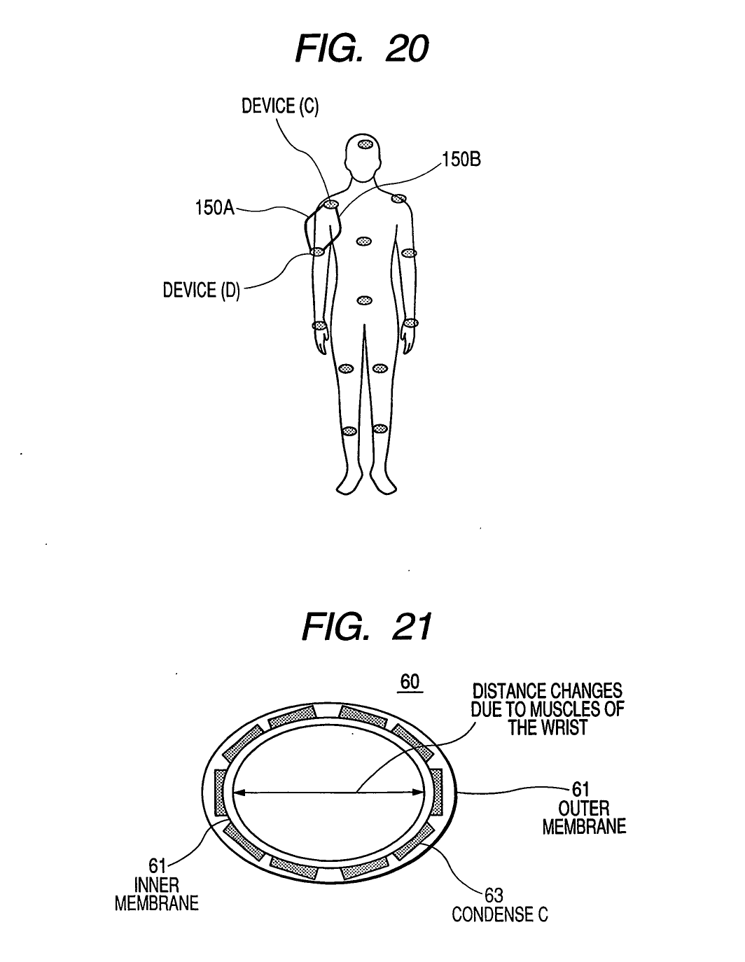

FIG. 20 shows a state in which the devices for generating an electrical signal corresponding to a change in posture in accordance with the invention shown in FIGS. 1 to 11 are applied to various parts of the body, and a pair of these devices are respectively connected to both ends of devices 150A and 150B for generating an electrical signal corresponding to a change in position, which are similar to the one shown in FIG. 17. The first-mentioned pair of devices are coupled to each other by means of the device 150A on the back side and by means of the device 150B on the breast side. In this state, in a case where the arm is moved toward the breast side, for instance, the device 150A extends and the device 150B shrinks. On the other hand, in a case where the arm in this state is moved toward the back side, the device 150B extends and the device 150A shrinks. Since the device 150A and the device 150B have the structure shown in FIG. 17, the amounts of extension or shrinkage of the device 150A and the device 150B can be obtained as the amounts of insertion or pulling-out displacement, i.e., changes in the electrostatic capacity, of the flexible insulator-coated conductor (core) 153 and the flexible hollow conductor 154.

### 11th Embodiment

FIG. 21 shows the device for generating an electrical signal corresponding to a change in position in accordance with the invention, which quantitatively detects a change in the expansion or contraction of muscles or the like by detecting a change in the electrostatic capacity based on a change in the distance between mutually opposing electrodes. In FIG. 21, reference numeral 60 denotes a device for generating an electrical signal corresponding to an amount of change in annular expansion or shrinkage; 61 and 62 respectively denote an outer membrane and an inner membrane, both of which are flexible and extensible. Reference numeral 63 denotes a capacitor, and a plurality of electrode pairs, which are opposed to each other and to which a voltage is applied, are disposed as the capacitors 63 in an annular space formed between the outer membrane 61 and the inner membrane 62. If this device is fitted around a wrist, for example, in terms of the size of the wrist when the fingers are stretched, the distance between the electrode pairs (capacitors) in the device changes due to the contraction of the muscles, and the electrostatic capacity changes. A change in this electrostatic capacity is obtained as an electrical signal.

If this device is made as a type in which it is fitted around the breast or worn as a wet suit, it is possible to quantitatively measure the respiratory action or the action of the entire body.

### 12th Embodiment

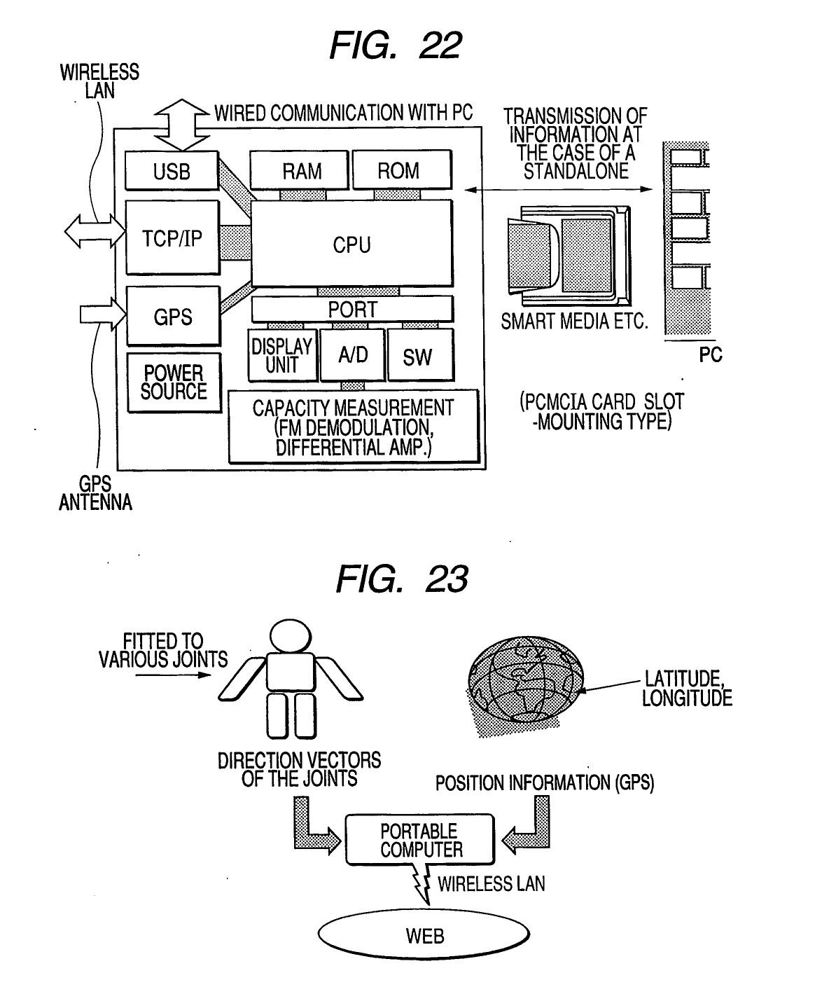

FIG. 22 shows an example of a configuration in which information from the device for generating an electrical signal corresponding to a change in position or posture in accordance with the invention is recorded in a memory of a Web server or a computer. As shown in FIG. 22, by designing a control unit (hereafter referred to as a Web PC) for controlling the device of the invention so as to be accommodated in a pocket, the Web PC can be carried easily, and it becomes possible to measure the posture (inclination) and the acceleration (displacement) of the measuring object in various places and scenes. In addition, if the configuration of the computer shown in FIG. 22 is used as a portable computer shown in FIG. 23, the device can be fitted to various parts of the human body, thereby making it possible to measure the position or posture. Further, if a GPS (Global Positioning System) is fitted to the user, it is possible to record where the user is located and what kind of action the user is taking, and the data can be delivered through the Internet. This means that it is easily possible to carry around a motion picture device which has conventionally been impossible to be fitted to the human body and carried around, and that direction vectors of various parts of the human body can be obtained as information.

In addition, since the Web PC has its original IP address, as the object-side Web PC is connected to the Internet, it becomes possible to deliver the action and posture of various parts of the body to user PCs throughout the world. Further, since a wireless LAN is used, if the devices are used in a local network environment, it becomes possible to easily obtain action data of several persons.

Furthermore, the object-side Web PC shown in FIG. 23 is characterized in that it is configured by one chip. In a case where communication is possible by effecting communication with a user PC on a wired or wireless basis, action data is recorded in the internal memory of the object-side Web PC in accordance with a program written in advance in a ROM. On a later day, by extracting the data from this memory, a complete action record of the user's one day can be obtained. For example, by applying the device to a sport player, the sport player's action during a game can be numerically recorded. Further, the device can be used not only on the human body but also in various fields including, for example, an apparatus for positioning a port on an implant for medical application, long-term measurement of the angle of inclination of a building, posture control of such as an automobile, aircraft, or a ship, and so forth.

FIG. 23 shows a schematic diagram of a case in which the Web PC shown in FIG. 22 is applied to the human body. As shown in FIG. 23, the devices are fitted to various parts of the body. In the embodiment shown in FIG. 23, a GPS is also applied to the body. Consequently, it is possible to know on the Internet the place (acquired through the GPS) where the user is located and what kind of action the user is taking. As shown in FIG. 22, the configuration provided is such that when the Internet is not available, the recording of data in the memory of the Web PC and the delivery of data on a wired basis are made possible. In addition, the GPS is required in a case where the measuring object wearing the devices moves; however, in a case where the measuring object does not move as in the case of a building, the GPS is not required.

### INDUSTRIAL APPLICABILITY

As described above, according the invention, it is possible to simultaneously detect changes in inclination (posture) in the X-axis direction, the Y-axis direction, and the Z-axis direction of the measuring object with an extremely compact and simple structure. The device for generating an electrical signal corresponding to a change in position or posture in accordance with the invention can be suitably used in applications to such as detection of diastrophism, a detecting element for posture control of a ship, aircraft, a motor vehicle, or the like, and detection of the action and posture of various parts of a human body. Further, the device can be suitably employed in applications to levels used in the fields of manipulators at plants, architecture, and civil engineering, as well as to a detecting element for controlling rocking in a mega-float, medical equipment requiring the measurement of a horizontal direction, and a damping device for controlling vibrations in a horizontal direction. Furthermore, the device can be suitably used in applications to a device for controlling a camera-shake preventing function in a camera or the like, posture control of a bipedal robot, an input device for measuring a direction for a computer, and inclination measuring devices for a steel tower, an electric pole, a bridge girder, or the like.

According to the second aspect of the invention, since the distance between the counter electrodes and the peripheral electrodes can be made close to each other, it is possible to overcome the problem that accurate detection of the electrostatic capacity becomes impossible when the free surface of the fluid dielectric is located in between the counter electrode and the peripheral electrode.

According to the third aspect of the invention, it is possible to detect even a change in the angle of inclination in units of seconds, and detect fine amounts of change in posture.

According to the fourth aspect of the invention, the amount of linear displacement of the measuring object can be detected with high accuracy. Therefore, the device can be suitably used in cases where the manufacturing process of precision machinery, the distance between respective joints of a robot, and the amount of displacement of members in a motor vehicle, aircraft, and the like are to be ascertained.

According to the fifth aspect of the invention, since it is possible to measure the amount of displacement of a curved locus, the device can be suitably used in the fields of civil engineering, architecture, and machinery.

According to the sixth aspect of the invention, it is possible to detect concurrently the amount of linear displacement between members and changes in the angle of inclination (posture) in the X-, Y-, and Z-axis directions of a member.

According to the seventh to 10th aspects of the invention, it is possible to concurrently detect the amount of displacement of various parts of a human body and a change in the posture thereof.

According to the 11th or 12th aspects of the invention, since the condition of breathing can be detected by wearing the devices on the breast, it is possible to automatically ascertain the symptom of apnea and reliably take a preventive measure by such as issuing an alarm.

1. A device for generating an electrical signal corresponding to a change in posture comprising:
a container (2) which is formed of an electrical insulating material and is tightly fixed to an electrode holder (1) formed of an electrical insulating material and in which a fluid dielectric (B) is sealed with a volume ratio sufficient to have an angle of inclination with respect to a free surface of the fluid dielectric;
a plurality of pairs of peripheral electrodes (4) disposed at positions in such a way that each of said plurality of pairs of peripheral electrodes are symmetrical arranged perpendicular to the electrode holder in respect of a central point of a cross section of the container so as to be apart from an inner peripheral surface of the container with a predetermined interval therefrom; and
a pair of counter electrodes (3), being electrically insulated from each other, which are opposed each other along an imaginary line perpendicular from a central point of the cross section of the container, each of said pair of counter electrodes being perpendicular to an upper surface of the electrode holder, serving as a bottom of the container, or perpendicular to a lower surface of a ceiling part of the container, characterized in that an external voltage is applied to the pair of counter electrodes so that an electrical signal corresponding to a change in posture can be generated.

2. The device for generating an electrical signal corresponding to a change in posture according to claim 1, wherein each of the counter electrodes (3) has a flat surface.

3. The device for generating an electrical signal corresponding to a change in posture according to claim 1, wherein each of the peripheral electrodes (4) extends from the ceiling and the bottom, respectively, of the container (2), and has a nonconductive portion or is split in an axial direction thereof.

4. The device for generating an electrical signal corresponding to a change in posture according to claim 3, wherein power supply electrodes integrally extend from the bottom to the ceiling of the container (2) instead of the counter electrodes (3).

5. A device for generating an electrical signal corresponding to a change in posture comprising:
a spherical container which is formed of an electrical insulating material and in which a plurality of electrodes, to which a voltage is applied and each has an arcuate surface, are fixed to an inner peripheral surface thereof vertically symmetrically, a fluid dielectric being sealed therein with a volume ratio sufficient to have an angle of inclination with respect to a free surface of the fluid dielectric; and
a pair of counter electrodes which are electrically insulated from each other and are respectively disposed at a lower end portion and an upper end portion which share a segment passing through a central point of the spherical container, a voltage being applied to the pair of counter electrodes.

6. A device for generating an electrical signal corresponding to a change in posture comprising:
a polygonal container which is formed of an electrical insulating material and in which a plurality of electrodes each having a flat surface are fixed to an inner peripheral surface thereof vertically symmetrically, a fluid dielectric being sealed therein with a volume ratio sufficient to have an angle of inclination with respect to a free surface of the fluid dielectric; and
a pair of counter electrodes which are electrically insulated from each other and are respectively disposed at mutually opposing portions of the container, a voltage being applied to the pair of counter electrodes.

7. The device for generating an electrical signal corresponding to a change in posture according to claim 1, wherein a high frequency voltage is applied to an electrical-signal generating means for outputting a voltage corresponding to a difference in an developing electrostatic capacity ascribable to a difference in an area of contact with the fluid dielectric between at least one pair of electrodes to which the voltage is applied in the container in which the fluid dielectric with a volume less than a content volume of the container is accommodated, frequency modulation corresponding to the inclination of the container is provided for a carrier wave generated by a high frequency oscillator, and this signal is subjected to FM demodulation.

8. (cancel)

9. (cancel)

10. A device for generating an electrical signal corresponding to a change in position or posture wherein the pair of the devices for generating an electrical signal corresponding to a change in posture according to claim 1 are respectively attached to both ends or spaced-apart midway portions of a device for generating an electrical signal corresponding to a change in position which comprises a hollow conductor, a conductor coated with an electrical insulating material and fitted in the hollow conductor, the conductor being linearly displaceable, means for applying a voltage across the hollow conductor and the conductor coated with the electrical insulating material, and means for obtaining as an electrical signal a change in electrostatic capacity corresponding to an amount of insertion or pulling-out displacement between the hollow conductor and the conductor coated with the electrical insulating material.

11. A device for generating an electrical signal corresponding to a change in position or posture wherein the pair of the devices for generating an electrical signal corresponding to a change in posture according to claims 1 are respectively attached to both ends or spaced-apart midway portions of a device for generating an electrical signal corresponding to a change in position which comprises a flexible hollow conductor, a flexible conductor coated with an electrical insulating material and fitted in the hollow conductor, the flexible conductor being linearly displaceable in an axial direction, means for applying a voltage across the flexible hollow conductor and the flexible conductor coated with the electrical insulating material, and means for obtaining as an electrical signal a change in electrostatic capacity corresponding to an amount of insertion or pulling-out displacement between the flexible hollow conductor and the flexible conductor coated with the electrical insulating material.

12. (cancel)

13. The device for generating an electrical signal corresponding to a change in posture according to claim 2, wherein each of the peripheral electrodes (4) extends from the ceiling and the bottom, respectively, of the container (2), and has a nonconductive portion or is split in an axial direction thereof.

14. The device for generating an electrical signal corresponding to a change in posture according to claim 13, wherein power supply electrodes integrally extend from the bottom to the ceiling of the container (2) instead of the counter electrodes (3).
